(19) United States
(12) Patent Application Publication
(10) Pub. No.: US 2008/0186762 A1
(43) Pub. Date: Aug. 7, 2008

(54) Phase-change memory element

(75) Inventors: Yen Chuo, Taipei City (TW); Frederick T. Chen, Hsinchu (TW)

Correspondence Address: BIRCH STEWART KOLASCH & BIRCH, PO BOX 747, FALLS CHURCH, VA, 22040-0747, US

(73) Assignees: Industrial Technology Research Institute, Hsinchu (TW); Powerchip Semiconductor Corp., Hsin-Chu (TW); NANYA TECHNOLOGY CORPORATION, Kueishan (TW); ProMOS Technologies Inc., Hsinchu (TW); Windbond Electronics Corp., Hsinchu (TW)

(21) Appl. No.: 12/010,761

(22) Filed: Jan. 29, 2008

(30) Foreign Application Priority Data
Feb. 1, 2007 (TW) 96103658

(51) Int. Cl. G11C 11/00

(52) U.S. Cl. 365/163

(57) ABSTRACT

A phase-change memory is provided. The phase-change memory comprises first and second electrodes, wherein the first and second electrodes comprise phase-change material. A conductive path is formed between the first and second electrodes and electrically connects the first and second electrodes, wherein the conductive path comprises an embedded metal layer and a phase-change layer resulting in current from the first electrode to the second electrode or from the second electrode to the first electrode passing through the embedded metal layer and the phase change layer.

### BACKGROUND OF THE INVENTION

1. Field of the Invention

The invention relates to a memory element, and more particularly to a phase-change memory element.

2. Description of the Related Art

Electronic devices use different types of memories, such as DRAM, SRAM and flash memory or a combination based on the requirements of the application, the operating speed, the memory size and the cost considerations of the equipment. Current developments in the memory technology field include FeRAM, MRAM and phase-change memory. Among these alternative memories, phase-change memory is most likely to be mass manufactured in the near, future.

Phase-change memory is targeted for applications currently utilizing flash non-volatile memory. Such applications are typically mobile devices which require low power consumption, and hence, minimal programming currents. A phase-change memory cell is designed with several goals in mind: low programming current, higher reliability (including electromigration risk), smaller cell size, and faster phase transformation speed. These requirements often set contradictory requirements on feature size, but a careful choice and arrangement of materials used for the components can often widen the tolerance.

To reduce the programming current, the most straightforward way is to shrink the heating area. A benefit of this strategy is simultaneous reduction of cell size. Assuming a fixed required current density, the current will shrink in proportion to the area. In reality, however, cooling becomes significant for smaller structures, and loss to surroundings becomes more important due to increasing surface/volume ratio. As a result, the required current density must increase as heating area is reduced. This poses an electromigration concern for reliability. Hence, it is important to use materials in the cell which do not pose an electromigration concern. It is also important to improve the heating efficiency, by increasing heating flux in the active programming region while reducing heat loss to the surroundings.

The requirements above are best served by sandwiching the heating region between two regions of phase-change material, for example the chalcogenide Ge₂Sb₂Te₅ (GST). The thermal conductivity of this material is notably low, about 0.2-0.3 W/m-K, due to the 20% presence of vacancies in the crystalline (fcc phase) microstructure. Heating is confined to a small area between a bottom and top portion of the chalcogenide material. A key aspect of this invention is the method of forming such a small area. The bottom portion is contained within a trench formed over the drain in one dimension, and the drain width in the other dimension. The top portion is an extended chalcogenide line perpendicularly oriented with respect to the trench formed over the drain. Preferably, this line is parallel to, of equal width to, and directly under the metal bit-line used to access the memory cell.

U.S. Pat. No. 5,789,758 assigned to Micron (“Chalcogenide Memory Cell with a Plurality of Chalcogenide Electrodes”) discloses a method for fabricating a phase-change memory element 10, referring to FIG. 1. First, a first electrode 15 is formed on a substrate 12, wherein the first electrode 15 comprises a phase-change layer 14 and a metal layer 13. Next, a dielectric layer 16 with an opening 17 is formed on the first electrode 15. Next, a phase-change layer 18 and a second electrode 20 are formed on the dielectric layer 16 and fill the opening 17, forcing the phase-change layer to contact the first electrode 15. Finally, a dielectric layer is formed to surround the second electrode. Formation of the pore in a dielectric layer is very difficult, and filling it with chalcogenide is even harder. Alternatively, formation of a chalcogenide island to be covered with dielectric is also difficult. Generally, three lithographic steps are needed to form this chalcogenide structure. It is desirable to minimize the number of lithographic steps in manufacture of the device.

Further, a conventional phase-change memory element (disclosed in “Novel cell structure of PRAM with thin film metal layer inserted SeSbTe” IEDM2003) comprises a T-shaped structure. Referring to FIG. 2, the phase-change memory element comprises a bottom electrode 40 formed on a substrate 30, and a dielectric layer 42 formed on the bottom electrode. The phase-change memory element further comprises a first phase-change layer 44, a metal layer 45, a second phase-change layer 46, and a top electrode 47 subsequently formed on the dielectric layer 42, wherein the first phase-change layer 44 electrically connects to the bottom electrode 40 via a bottom contact 43 and the second phase-change layer 46 electrically connects to the top electrode 47 via a top contact 48. The conventional phase-change memory element has reduced contact area between the phase-change layer and electrode layer. The phase-change layer, however, is apt to transport heat to outside, since the top and bottom contacts are surrounded by dielectric layer.

### BRIEF SUMMARY OF THE INVENTION

An exemplary embodiment of a phase-change memory element comprises first and second electrodes, wherein the first and second electrodes comprise phase-change material. A conductive path is formed between the first and second electrodes and electrically connects the first and second electrodes, wherein the conductive path comprises an embedded metal layer and a phase-change layer resulting in current from the first electrode to the second electrode or from the second electrode to the first electrode passing through the embedded metal layer and the phase change layer.

According to another embodiment of the invention, a phase-change memory element comprises a substrate, a first electrode formed on the substrate, an embedded metal layer formed on the first electrode and electrically connected to the first electrode, a dielectric layer with an opening formed on the embedded metal layer, and a second electrode formed on the dielectric layer and electrically connected to the embedded metal layer via the opening, wherein the first electrode and second electrode comprise phase-change material.

Further, a phase-change memory element according to some embodiments of the invention comprises a substrate, a first electrode formed on the substrate, a dielectric layer with an opening formed on the first electrode, an embedded metal layer formed into the opening, and a second electrode formed on the embedded metal layer, wherein the first electrode and second electrode comprise phase-change material.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1 and 2 are cross sections of conventional phase-change memory elements.

FIGS. 3a and 3d are cross sections of a method of fabricating a phase-change memory element according to an embodiment of the invention.

FIGS. 4a and 4b are cross sections of a method of fabricating a phase-change memory element according to another embodiment of the invention.

FIGS. 5a and 5e are cross sections of a method of fabricating a phase-change memory element according to still another embodiment of the invention.

FIGS. 6a and 6c are cross sections of a method of fabricating a phase-change memory element according to yet another embodiment of the invention.

FIG. 7 is a cross section of a phase-change memory element according to some embodiments of the invention.

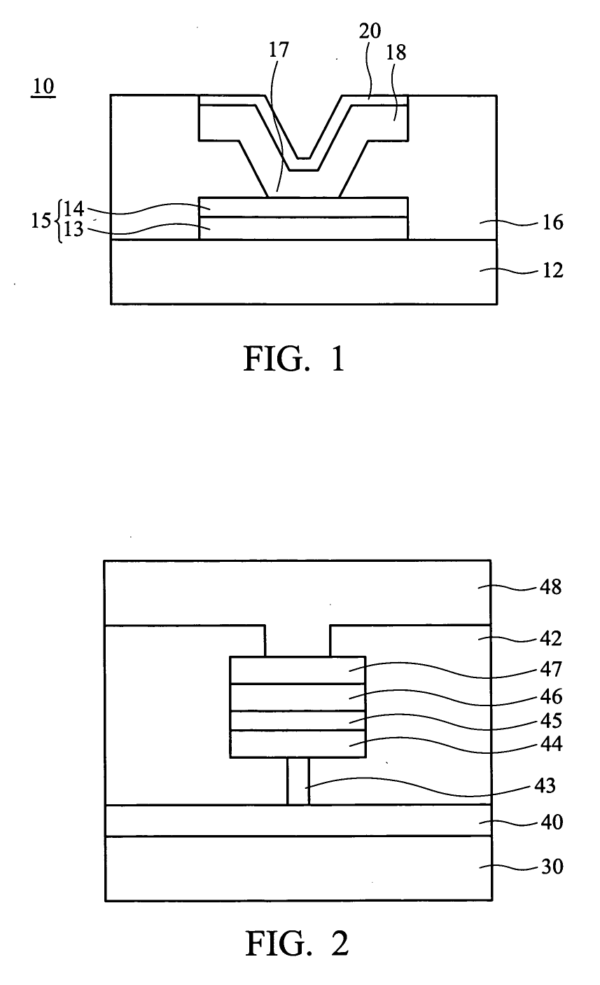

### DETAILED DESCRIPTION OF THE INVENTION

The following description is of the mode of carrying out the invention. This description is made for the purpose of illustrating the general principles of the invention and should not be taken in a limiting sense. The scope of the invention is best determined by reference to the appended claims.

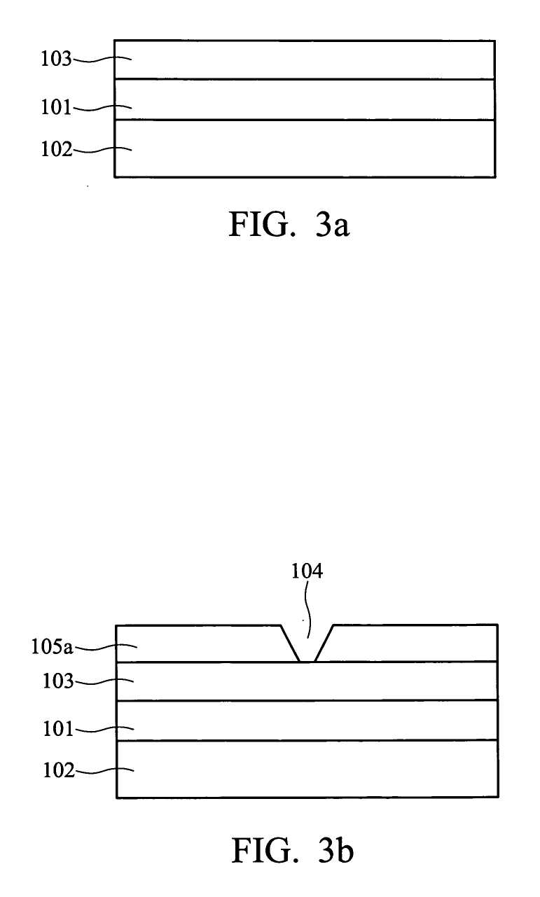

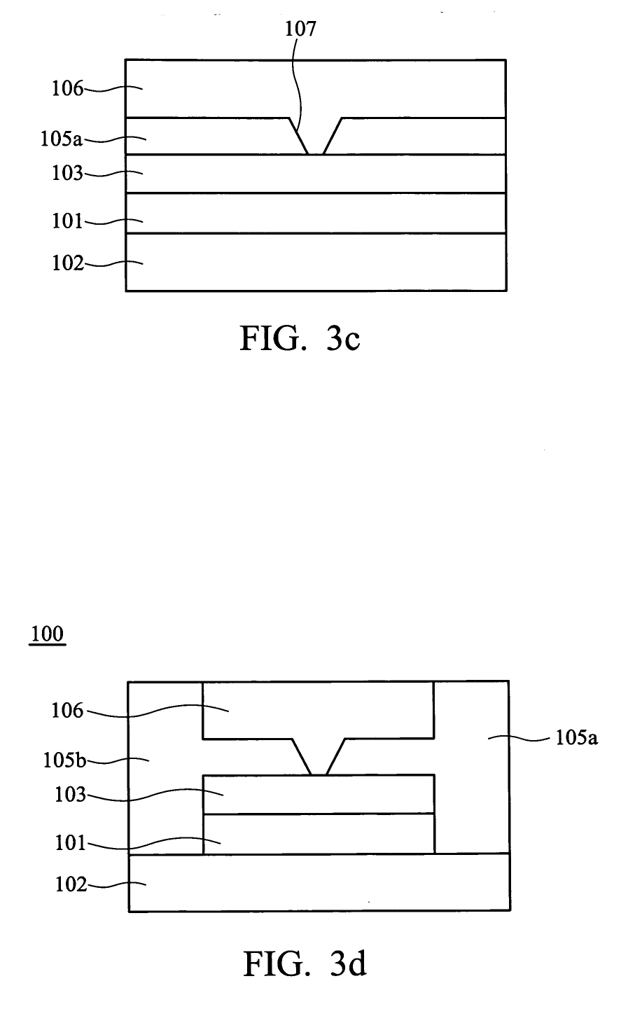

First, referring to FIG. 3a, a first electrode 101 is formed on a substrate 102. Next, an embedded metal layer 103 (serving as conductive path) is formed on the first electrode 101. Particularly, the substrate 102 can be a substrate employed in a semiconductor process, such as silicon substrate. The substrate 102 can be a substrate comprising a complementary metal oxide semiconductor (CMOS) circuit, isolation structure, diode, or capacitor. The accompanying drawings show the substrate 102 in a plain rectangle in order to simplify the illustration. Suitable material for the first electrode 101 can be phase-change material such as chalcogenide (In, Ge, Sb, Te or combinations thereof), for example GeSbTe or InGeSbTe. Suitable material for the embedded metal layer 103 can be Ti-containing compound or cermets, such as Al, W, Mo, TiN, or TiW. It should be noted that one feature of the invention is to provided the metal layer embedded into the phase change material layer to improve heating absorbability and efficiency. We can further modify the location, resistance, and thickness in order to optimize the heating absorbability and efficiency. The embedded metal layer 103 can have a thickness of 1 nm˜200 nm, or 5 nm0 nm, or 10 nm. Further, the embedded metal layer can have a resistivity of 10 E-1 Ω*cm˜10 E-8 Ω*cm, or 10 E-2 Ω*cm˜10 E-5 Ω*cm, or 10 E-3 Ω*cm.˜5

Next, referring to FIG. 3b, a dielectric layer is formed on the embedded metal layer 103, wherein the dielectric layer can be silicon-containing compound, such as silicon nitride or silicon oxide. Next, the dielectric layer is patterned to form a patterned dielectric layer 105a with an opening 104. Next, a second electrode 106 is blanketly formed on the structure, referring to FIG. 3c. Herein, the opening 104 can have tapered sidewalls 107 facilitating the formation of second electrode 106 formed subsequently and electrically connected to the embedded metal layer 103. Further, the dimension of the opening can be less than the resolution limit of photolithography process.

It should be noted that the second electrode 106 can be phase-change material such as chalcogenide (In Ge, Sb, Te or combinations thereof), for example GeSbTe or InGeSbTe. Finally, referring to FIG. 3d, the dielectric layer is patterned and a dielectric layer 105b is formed to surround the electrodes to form isolated phase-change memory element 100.

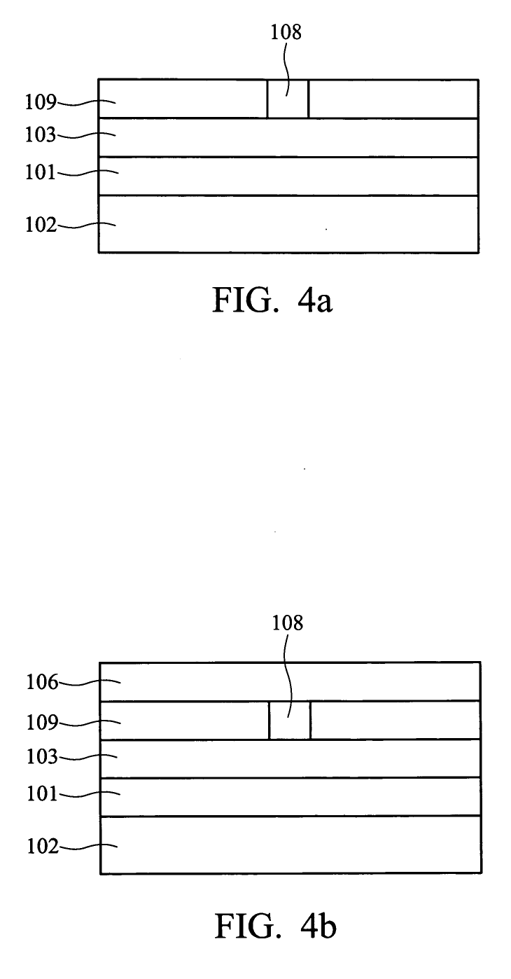

According to another embodiment of the invention, after the process as disclosed in FIG. 3a, a pillar of phase-change layer 108 is formed on the embedded metal layer 103. Next, a dielectric layer 109 is formed on the substrate and etched back (or planarized) to expose the top surface of the phase-change layer 108 (serving as conductive path), as shown in FIG. 4a. It should be noted that the pillar of phase-change layer 108 can be made via patterns transfer with a trimmed photoresist pillar serving as mask. Further, the dimension of the pillar 108 can be further reduced with a hard mask having a dimension less than the resolution limit of photolithography process, wherein the hard mask is formed by interlaced sidewall-spacer process. Next, referring to FIG. 4b, a second electrode 106 is formed on the dielectric layer 109 and electrically connected to the embedded metal layer 103 via the pillar of phase-change layer 108.

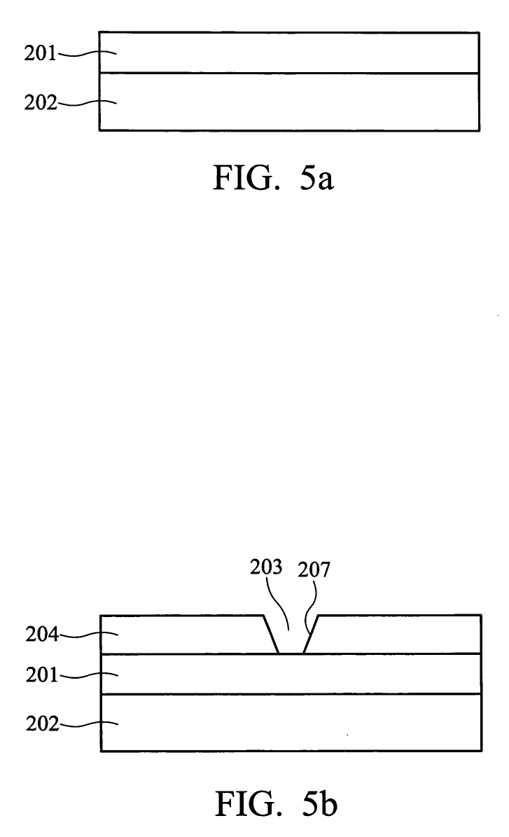

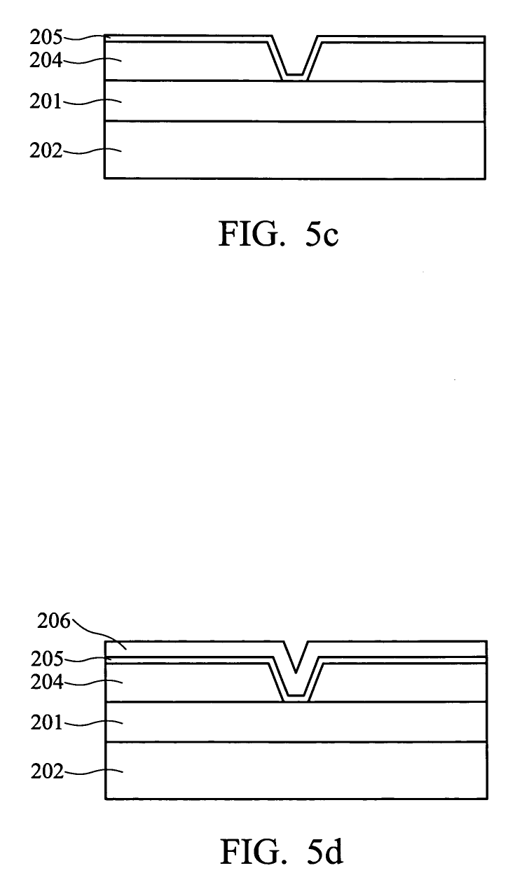

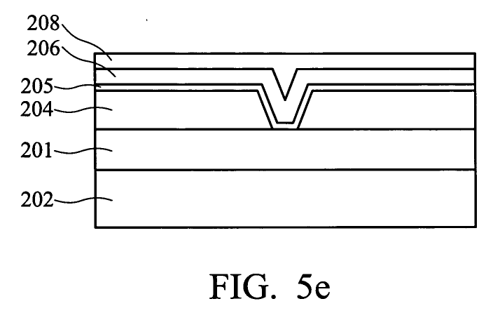

FIGS. 5a to 5d are sectional diagrams illustrating another embodiment of the manufacturing process of the phase-change memory element 200.

First, referring to FIG. 5a, a first electrode 201 is formed on the substrate 202. Particularly, the substrate 202 can be a substrate employed in a semiconductor process, such as silicon substrate. The substrate 202 can be a substrate comprising a complementary metal oxide semiconductor (CMOS) circuit, isolation structure, diode, or capacitor. The accompanying drawings show the substrate 202 in a plain rectangle in order to simplify the illustration. Suitable material for the first electrode 201 can be phase-change material such as chalcogenide (In Ge, Sb, Te or combinations thereof), for example GeSbTe or InGeSbTe.

Next, referring to FIG. 5b, a dielectric layer is formed on the first electrode 201. The dielectric layer can be silicon-containing compound, such as silicon nitride or silicon oxide. Next, the dielectric layer is patterned to form a patterned dielectric layer 204 with an opening 203. Next, a phase-change layer 205 is conformally formed on the structure, as shown in FIG. 5c. Next, an embedded metal layer 206 is conformally formed on the phase-change layer 205, as shown in FIG. 5d.

Herein, the opening 203 can have tapered sidewalls 207 facilitating the formation of phase-change layer 205. Further, the dimension of the opening 203 can be further reduced by partially filling a dielectric spacer on the sidewalls thereof.

Suitable material for the embedded metal layer 206 can be Ti-containing compound or cermets, such as Al, W, Mo, TiN, or TiW. It should be noted that one feature of the invention is to provided the metal layer embedded into the phase change material layer to improve heating absorbability and efficiency. We can further modify the location, resistance, and thickness in order to optimize the heating absorbability and efficiency. Moreover, the embedded metal layer 206 can have a thickness of 1 nm˜200 nm, or 5 nm˜50 nm, or 10 nm. Further, the embedded metal layer can have a resistivity of 10 E-1 Ω*cm˜10 E-8 Ω*cm, or 10 E-2 Ω*cm˜10 E-5 Ω*cm, or 10 E-3 Ω*cm.

Finally, referring to FIG. 5e, a second electrode 208 is formed on the structure. It should be noted that the second electrode 208 can be phase-change material such as chalcogenide (In, Ge, Sb, Te or combinations thereof), for example GeSbTe or InGeSbTe.

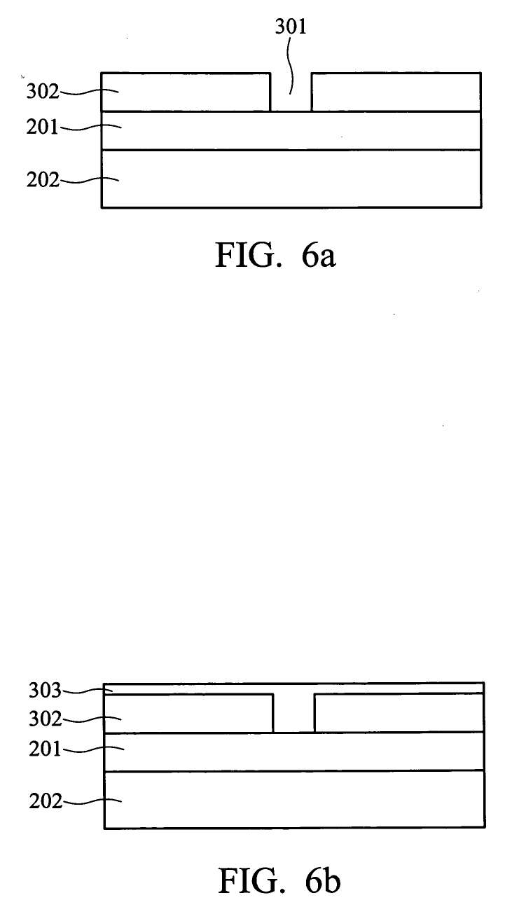

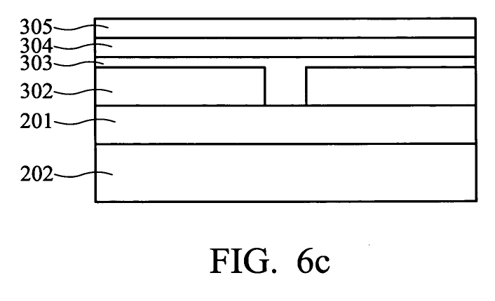

According to another embodiment of the invention, after the process disclosed in FIG. 5a, a dielectric layer 302 with an opening 301 is formed on the first electrode 201, referring to FIG. 6a. Further, the dimension of the via hole 301 can be further reduced by partially filling a dielectric spacer on the sidewalls thereof. Next, referring to FIG. 6b, a phase-change layer 303 blanketly formed on the above structure and filled into the opening 301. Finally, an embedded metal layer 304 and a second electrode 305 are subsequently formed on the phase-change layer 303, referring to FIG. 6c. Suitable material for the second electrode 305 can be phase-change material such as chalcogenide (Ge, Sb, Te or combinations thereof), for example GeSbTe or InGeSbTe. It should be noted that the embedded metal layer 304 does not directly contact the phase-change layer 303 within the opening 301. In an embodiment of the invention, a pillar of phase-change layer can be formed and a dielectric layer subsequently formed to surround the pillar of phase-change layer. Next, a phase-change layer is formed to contact the pillar of phase-change layer.

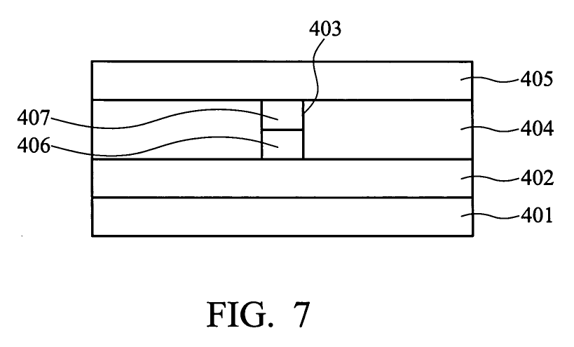

Referring to FIG. 7, an embodiment of the invention provides a phase-change memory element 400 comprising a substrate 401, a bottom electrode 402, a dielectric layer 404 with an opening 403, and a top electrode 405, wherein the phase-change memory element 400 comprises a conductive path within the opening 403. Particularly, the conductive path comprises a phase-change layer 406 and an embedded metal layer 407.

Accordingly, since the embedded metal layer improves the heating efficiency, the disclosed phase-change memory element allows reduction of both programming current and programming voltage. Compared to conventional structure, the disclosed phase-change memory element exhibits excellent temperature uniformity when applying a voltage pulse. Moreover, the fabrication process is relatively simple and can accommodate various cell designs, and low cost can be maintained.

While the invention has been described by way of example and in terms of embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising:
a first electrode and a second electrode, wherein the first electrode and the second electrode comprise phase-change material; and
a conductive path formed between the first electrode and the second electrode and electrically connected the first electrode and the second electrode, wherein the conductive path comprises a phase-change layer and a embedded metal layer and an electric current passes through the phase-change layer and a embedded metal layer when applying a bias voltage to the phase-change memory element.

2. The phase-change memory element as claimed in claim 1, wherein the phase-change layer is a part of the first electrode.

3. The phase-change memory element as claimed in claim 1, wherein the phase-change layer is a part of the second electrode.

4. The phase-change memory element as claimed in claim 1, wherein the phase-change material comprises chalcogenide.

5. The phase-change memory element as claimed in claim 1, wherein the first electrode serves as a top electrode and the second electrode serves as a bottom electrode, and the embedded metal layer directly contacts the first electrode.

6. The phase-change memory element as claimed in claim 1, wherein the embedded metal layer comprises Ti-containing compound or cermets.

7. The phase-change memory element as claimed in claim 1, wherein the embedded metal layer has a thickness of 1 nm˜200 nm.

8. The phase-change memory element as claimed in claim 1, wherein the embedded metal layer has a resistivity of 10 E-1 Ω*cm˜10 E-8 Ω*cm.

9. A phase-change memory element, comprising:
a substrate;
a first electrode formed on the substrate;
an embedded metal layer formed on the first electrode and electrically connected to the first electrode;
a dielectric layer with an opening formed on the embedded metal layer; and
a second electrode formed on the dielectric layer and electrically connected to the embedded metal layer via the opening, wherein the first electrode and second electrode comprise phase-change material.

10. The phase-change memory element as claimed in claim 9, wherein the phase-change material comprises chalcogenide.

11. The phase-change memory element as claimed in claim 9, further comprising a pillar of phase-change layer within the opening.

12. The phase-change memory element as claimed in claim 9, wherein the embedded metal layer directly contacts to the first electrode.

13. The phase-change memory element as claimed in claim 9, wherein the embedded metal layer comprises Ti-containing compound or cermets .

14. The phase-change memory element as claimed in claim 9, wherein the embedded metal layer has a thickness of 1 nm˜200 nm.

15. The phase-change memory element as claimed in claim 9, wherein the embedded metal layer has a resistivity of 10 E-1 Ω*cm˜10 E-8 Ω*cm.

16. A phase-change memory element, comprising:
a substrate;
a first electrode formed on the substrate;
a dielectric layer with an opening formed on the first electrode;
an embedded metal layer formed into the opening; and
a second electrode formed on the embedded metal layer, wherein the first electrode and second electrode comprises phase-change material.

17. The phase-change memory element as claimed in claim 16, further comprising a pillar of phase-change layer formed into the opening.

18. The phase-change memory element as claimed in claim 17, wherein the embedded metal layer is formed on the dielectric layer and electrically connected to the first electrode.

19. The phase-change memory element as claimed in claim 16, wherein the phase-change material comprises chalcogenide.

20. The phase-change memory element as claimed in claim 16, wherein the embedded metal layer comprises Ti-containing compound or cermets.

21. The phase-change memory element as claimed in claim 16, wherein the embedded metal layer has a thickness of 1 nm-200 nm.

22. The phase-change memory element as claimed in claim 16, wherein the embedded metal layer has a resistivity of 10 E-1 Ω*cm˜10 E-8 Ω*cm.
